(19) United States
(12) Patent Application Publication
(10) Pub. No.: US 2024/0130152 A1
(43) Pub. Date: Apr. 18, 2024

(54) DISPLAY APPARATUS

(71) Applicant: LG Display Co., Ltd., Seoul (KR)

(72) Inventors: JunHo YOUN, Paju-si (KR); HeumeIl BAEK, Paju-si (KR)

(21) Appl. No.: 18/350,545

(22) Filed: Jul. 11, 2023

(30) Foreign Application Priority Data
Oct. 13, 2022 (KR) 10-2022-0131820

(51) Int. Cl. H10K 50/15

(52) U.S. Cl. CPC H10K 50/15; H10K 2102/351

(57) ABSTRACT

A display apparatus includes a substrate, a first electrode disposed on the substrate, a lower organic layer disposed on the first electrode, a light emitting layer disposed on the lower organic layer, and a second electrode disposed on the light emitting layer. The lower organic layer has a cross-sectional profile including a plurality of curved surfaces.

### CROSS-REFERENCE TO RELATED APPLICATIONS

This application claims the benefit of and priority to Korean Patent Application No. 10-2022-0131820 filed on Oct. 13, 2022 in the Republic of Korea, which is incorporated herein by reference for all purposes as if fully set forth herein.

### BACKGROUND

### Technical Field

The present disclosure relates to a display apparatus, and more particularly, to a display apparatus having an improvement in luminance viewing angle while having excellent efficiency.

### Discussion of the Related Art

Recently, as our society advances toward an information-oriented society, the field of display apparatuses for visually displaying an electrical information signal has rapidly advanced. The development of various display apparatuses having excellent performance in terms of thinness, lightness, and low power consumption, is being conducted correspondingly. Examples of such display apparatuses may include a liquid crystal display apparatus (LCD), an organic light emitting display apparatus (OLED), and the like.

An organic light emitting display apparatus is a self-emission display apparatus, and can be manufactured to be light and thin since it does not require a separate light source, unlike a liquid crystal display apparatus having a separate light source. Further, the organic light emitting display apparatus has advantages in terms of power consumption due to a low voltage driving, and is excellent in terms of a color implementation, a response speed, a viewing angle, and a contrast ratio (CR).

### BRIEF SUMMARY

A light emitting layer of a display apparatus may be formed by a deposition process or a solution process. When the light emitting layer is formed by the deposition process, a surface of the light emitting layer is formed flat. The display apparatus including the light emitting layer formed by the deposition process has a relatively high efficiency but has a narrow luminance viewing angle. Unlike this, the light emitting layer formed by the solution process does not have a flat surface and has a profile shape that varies depending on characteristics of ink for forming the light emitting layer. The display apparatus including the light emitting layer formed by the solution process has relatively low emission efficiency and a wide luminance viewing angle.

One or more aspects of the present disclosure are to provide a display apparatus having a wide luminance viewing angle while maintaining high efficiency and lifetime characteristics.

A display apparatus according to an example embodiment of the present disclosure may comprise a substrate, a first electrode disposed on the substrate, a lower organic layer disposed on the first electrode, a light emitting layer disposed on the lower organic layer, and a second electrode disposed on the light emitting layer. The lower organic layer has a cross-sectional profile including a plurality of curved surfaces.

According to one or more embodiments of the present disclosure, the organic layer under the light emitting layer has a cross-sectional profile including a plurality of curved surfaces, the light emitting layer having a non-flat profile may be formed on an upper portion of the organic layer by a deposition process. The light emitting layer thus formed has a profile including a plurality of curved surfaces, but has a constant thickness.

Accordingly, in the display apparatus according to one or more embodiments of the present disclosure, a thickness of the light emitting layer in sub-pixels is constant, so that high emission efficiency can be maintained. At the same time, since layers between an anode and a cathode have a change in thickness, a multi-cavity effect is provided, so an effect of increasing a luminance viewing angle is provided.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the claims. Nothing in this section should be taken as a limitation on those claims. Further aspects and advantages are discussed below in conjunction with aspects of the disclosure.

It is to be understood that both the foregoing description and the following description of the present disclosure are illustrative and explanatory and are intended to provide further explanation of the disclosure.

### BRIEF DESCRIPTION OF THE SEVERAL VIEWS OF THE DRAWINGS

The accompanying drawings, which are included to provide a further understanding of the disclosure, are incorporated in and constitute a part of this disclosure, illustrate aspects and embodiments of the disclosure and together with the description serve to explain the principles of the disclosure.

FIG. 1 illustrates a cross-sectional view of a display apparatus according to an example embodiment of the present disclosure.

FIG. 2 is a view for explaining a cross-sectional profile of a hole transport layer according to an example embodiment of the present disclosure.

FIG. 3 illustrates a cross-sectional view of a display apparatus according to another example embodiment of the present disclosure.

FIG. 4 is a view for explaining a cross-sectional profile of a hole transport layer according to another example embodiment of the present disclosure.

FIG. 5 illustrates a cross-sectional view of a display apparatus according to another example embodiment of the present disclosure.

FIG. 6 is a view for explaining a cross-sectional profile of a hole transport layer according to still another example embodiment of the present disclosure.

FIG. 7 is a graph showing a thickness profile of a hole injection layer having a ∩-shape.

FIG. 8 is a graph showing a change in viewing angle according to a difference (Δ) between a smallest thickness and a greatest thickness of a hole injection layer having a ∩-shape.

FIG. 9 is a graph showing a change in efficiency according to the difference (Δ) between the smallest thickness and the greatest thickness of a hole injection layer having ∩-shape.

FIG. 10 is a graph showing a thickness profile of a hole transport layer according to Experimental Example 2B.

FIG. 11 is a graph showing changes in luminance viewing angle of a hole injection layer having a U-shape.

FIG. 12 is a graph showing changes in color viewing angle of the hole injection layer having a U-shape.

FIG. 13 is a graph showing a thickness profile of a hole injection layer having a W-shape.

FIG. 14 is a graph showing changes in viewing angle according to a difference (Δ) between a smallest thickness and a greatest thickness of the hole injection layer having a W-shape.

FIG. 15 is a graph showing changes in efficiency according to the difference (Δ) between the smallest thickness and the greatest thickness of the hole injection layer having a W-shape.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION

Reference is now made in detail to embodiments of the present disclosure, examples of which may be illustrated in the accompanying drawings. In the following description, when a detailed description of well-known functions or configurations may unnecessarily obscure aspects of the present disclosure, the detailed description thereof may be omitted for brevity. The progression of processing steps and/or operations described is an example; however, the sequence of steps and/or operations is not limited to that set forth herein and may be changed, with the exception of steps and/or operations necessarily occurring in any particular order.

Advantages and features of the present disclosure, and implementation methods thereof, are clarified through the example embodiments described with reference to the accompanying drawings. The present disclosure may, however, be embodied in different forms and should not be construed as limited to the example embodiments set forth herein. Rather, these example embodiments are examples and are provided so that this disclosure may be thorough and complete to assist those skilled in the art to fully understand the present disclosure without limiting the protected scope of the present disclosure.

The shapes, sizes, areas, ratios, angles, numbers, and the like disclosed in the drawings for describing various example embodiments of the present disclosure are merely an example, and thus, the present disclosure is not limited to the illustrated details. Like reference numerals refer to like elements throughout.

Where the term “comprise,” “have,” “include,” “contain,” “constitute,” “made up of,” “formed of,” or the like is used, one or more other elements may be added unless the term, such as “only” or the like is used. The terms used in the present disclosure are merely used in order to describe example embodiments, and are not intended to limit the scope of the present disclosure. The terms used herein are merely used in order to describe example embodiments, and are not intended to limit the scope of the present disclosure. The terms of a singular form may include plural forms unless the context clearly indicates otherwise. The word “example” is used to mean serving as an example or illustration. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing positional relationships, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” “adjacent to,” “besides,” or “next to” another structure, this description should be construed as including a case in which the structures contact each other as well as a case in which one or more additional structures are disposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like a case that is not consecutive or not sequential may be included unless a more limiting term, such as “just,” “immediate(ly),” or “direct(ly)” is used.

It will be understood that, although the term “first,” “second,” or the like may be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these terms are not used to define the essence, basis, order, or number of the elements.

For the expression that an element or layer is “connected,” “coupled,” “attached,” or “adhered” to another element or layer the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified. For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two. In one or more aspects, the phrases “one or more among” and “one or more of” may be used interchangeably simply for convenience unless stated otherwise.

Features of various embodiments of the present disclosure may be partially or wholly coupled to or combined with each other, and may be variously inter-operated, linked or driven together. Embodiments of the present disclosure may be carried out independently from each other, or may be carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

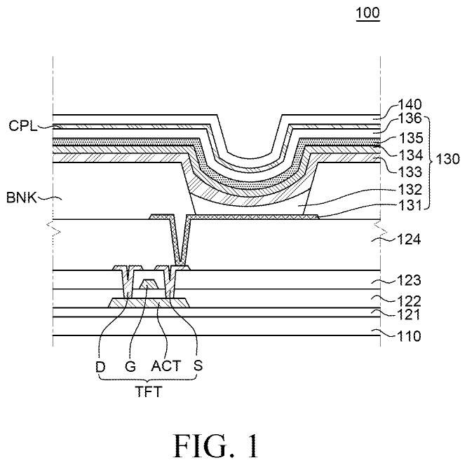

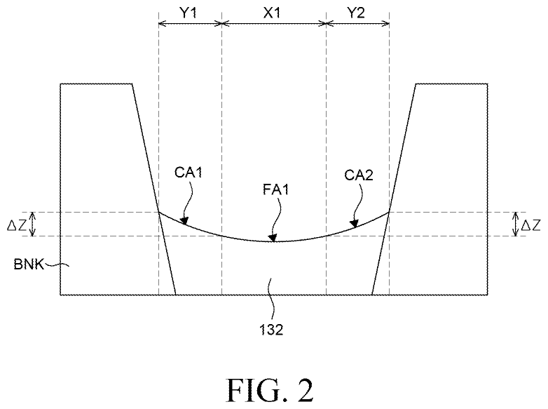

FIGS. 1 and 2 are views for explaining a display apparatus according to an example embodiment of the present disclosure. FIG. 1 is a cross-sectional view of a display apparatus according to an example embodiment of the present disclosure. FIG. 2 is a view for explaining a cross-sectional profile of a hole transport layer according to an example embodiment of the present disclosure. FIGS. 1 and 2 illustrate that a display apparatus 100 is driven in a top emission method, but embodiments of the present disclosure are not limited thereto. In FIG. 2, only a bank and a hole transport layer are shown for convenience of explanation, and an illustration of other components may be omitted.

A display apparatus 100 according to an example embodiment of the present disclosure includes a substrate 110, a thin film transistor TFT, a planarization layer 124, a light emitting device 130, a capping layer CPL, and a protective layer 140. The light emitting device 130 includes a first electrode 131, a hole injection layer 132, a light emitting layer 133, an electron transport layer 134, an electron injection layer 135, and a second electrode 136.

The display apparatus 100 according to an example embodiment of the present disclosure includes a display area and a non-display area. The display area may be an area in which a plurality of pixels are disposed to substantially display an image. The pixels including emission areas configured to display an image and driving circuits configured to drive the pixels may be disposed in the display area. The non-display area surrounds the display area. The non-display area is an area in which images are not substantially displayed, and various lines, a printed circuit board, and the like for driving the pixels and driving circuits disposed in the display area are disposed in the non-display area. For example, various driving circuits such as a gate driving circuit and a data driving circuit, and signal lines may be disposed in the non-display area.

The plurality of pixels may be disposed in a matrix shape, and each of the plurality of pixels includes a plurality of sub-pixels. The sub-pixel is an element for displaying one color, and includes an emission area in which light is emitted and a non-emission area in which light is not emitted. Each of the plurality of sub-pixels may be any one of a red sub-pixel, a green sub-pixel, a blue sub-pixel, and a white sub-pixel. In FIG. 1, only one sub-pixel is shown for convenience of explanation.

The substrate 110 is a substrate supporting various elements for driving the display apparatus 100. The substrate 110 may be formed of a material having excellent insulating properties and moisture permeability resistance. For example, the substrate 110 may be a glass substrate or a plastic substrate, but embodiments of the present disclosure are not limited thereto. For example, the plastic substrate may be formed of one or more materials from among polyethylene phthalate, polyimide, polyamide, and polycarbonate, but embodiments of the present disclosure are not limited thereto.

A buffer layer 121 is disposed on the substrate 110. The buffer layer 121 improves adhesion between an active layer ACT or various conductive material layers disposed on the substrate 110, and the substrate 110. Further, the buffer layer 121 may block foreign substances on the substrate 110 or oxygen and moisture introduced from the outside. The buffer layer 121 may be formed of a single layer or may be formed of multiple layers. For example, the buffer layer 121 may be formed of an inorganic material such as silicon oxide, silicon nitride, or silicon oxynitride, but embodiments of the present disclosure are not limited thereto.

The thin film transistor TFT is disposed on the buffer layer 121. In the drawings, only a driving thin film transistor among various thin film transistors that may be included in the display apparatus 100 is shown for convenience, but a switching thin film transistor and a capacitor may also be included.

The thin film transistor TFT is an element for driving the light emitting device 130. The thin film transistor TFT includes a gate electrode G, the active layer ACT, a source electrode S, and a drain electrode D.

The active layer ACT is disposed on the buffer layer 121. The active layer ACT may be formed of a metal oxide semiconductor. A gate insulating layer 122 may be disposed on the active layer ACT. For example, the gate insulating layer 122 may be formed of an inorganic material such as silicon oxide, silicon nitride, or silicon oxynitride, but embodiments of the present disclosure are not limited thereto. Further, the gate insulating layer 122 may be formed of a single layer or multiple layers.

The gate electrode G is disposed on the gate insulating layer 122. An interlayer insulating layer 123 is disposed on the gate electrode G to cover the gate electrode G. For example, the interlayer insulating layer 123 may be formed of an inorganic material such as silicon oxide, silicon nitride, or silicon oxynitride, but embodiments of the present disclosure are not limited thereto. Further, the interlayer insulating layer 123 may be formed of a single layer or multiple layers.

Each of the source electrode S and the drain electrode D is disposed on the interlayer insulating layer 123 and is electrically connected to the active layer ACT through contact holes penetrating the gate insulating layer 122 and the interlayer insulating layer 123. A structure of the thin film transistor TFT is not limited thereto and may be variously changed as needed.

The planarization layer 124 is disposed to cover the thin film transistor TFT. The planarization layer 124 planarizes an upper surface of the thin film transistor TFT. The planarization layer 124 may be formed of an organic material to easily provide a planarized surface. For example, the planarization layer 124 may be formed of one of polyimide, benzocyclobutyne-based resin, and acrylate-based resin, but embodiments of the present disclosure are not limited thereto. The planarization layer 124 may include a contact hole so that the source electrode S or drain electrode D of the thin film transistor TFT may be electrically connected to the first electrode 131.

The light emitting device 130 is disposed on the planarization layer 124. The light emitting device 130 may be disposed to correspond to each of the plurality of sub-pixels. The light emitting device 130 may include a first electrode 131, a hole injection layer 132, a light emitting layer 133, an electron transport layer 134, and a second electrode 136, but embodiments of the present disclosure are not limited thereto. For example, the light emitting device 130 may be an organic light emitting device, but embodiments of the present disclosure are not limited thereto.

The first electrode 131 is disposed on the planarization layer 124. The first electrode 131 is formed to be separated for each of the plurality of sub-pixels. The first electrode 131 is electrically connected to the source electrode S or the drain electrode D of the thin film transistor TFT through the contact hole. The first electrode 131 may be an electrode functioning as an anode of the organic light emitting device 130. The first electrode 131 is a component for supplying holes to the light emitting layer 133 and is formed of a conductive material having a high work function. For example, the first electrode 131 may be formed of one or more of transparent conductive oxides such as indium tin oxide (ITO), indium zinc oxide (IZO), indium tin zinc oxide (ITZO), tin oxide (SnO₂), zinc oxide (ZnO), indium copper oxide (ICO), and aluminum-doped zinc oxide (Al-doped ZnO, AZO), but embodiments of the present disclosure are not limited thereto. When the display apparatus 100 is driven in the top emission method, the first electrode 131 may have a structure in which a layer formed of a transparent conductive oxide and a reflective layer formed of a metal material are stacked. The reflective layer is formed of a metal having high reflectivity so that light emitted from the light emitting layer 133 can be reflected upward.

A bank BNK may be disposed on the planarization layer 124 and the first electrode 131. The bank BNK refers to an emission area of the light emitting layer 133. For example, the bank BNK may be disposed on the planarization layer 124 to expose at least a portion of the first electrode 131. The bank BNK may be disposed on the planarization layer 124 to cover an end portion of the first electrode 131. For example, the bank BNK may be formed of a hydrophobic organic material. The hole injection layer 132 to be described later is formed by a solution process. When the bank BNK is formed of a hydrophobic organic material, the solution process of the hole injection layer 132 may be easily facilitated.

The lower organic layer is disposed on the first electrode 131. The lower organic layer may be an organic layer disposed between the first electrode 131 and the light emitting layer 133. For example, the lower organic layer may be at least one of a hole injection layer and a hole transport layer. Hereinafter, the lower organic layer is exemplified as the hole injection layer 132, but embodiments of the present disclosure are not limited thereto.

The hole injection layer 132 is disposed on the first electrode 131. The hole injection layer 132 improves interface characteristics between the first electrode 131 and the light emitting layer 133 so that holes supplied from the first electrode 131 are easily injected into the light emitting layer 133. The hole injection layer 132 may be formed to be separated for each of the plurality of sub-pixels to correspond to the first electrode 131.

The hole injection layer 132 has a cross-sectional profile including a plurality of curved surfaces on a side facing towards the light emitting layer 133. For example, the hole injection layer 132 may have a cross-sectional profile of a U-shape. When a light emitting material is deposited on the hole injection layer 132 having the cross-sectional profile, the light emitting material is conformally deposited along a surface of the hole injection layer 132. For example, the light emitting layer 133 formed on the hole injection layer 132 by a deposition process is formed to have a constant thickness along the cross-sectional profile of the hole injection layer 132 in the emission area. Accordingly, the thickness of the light emitting layer 133 is constant, but a total thickness of layers stacked between the first electrode 131 and the second electrode 136 is not constant. Due to a change in the thickness of the layers stacked between the first electrode 131 and the second electrode 136, a multi-cavity effect may be obtained, so that a luminance viewing angle of the display apparatus can increase. For example, the layers stacked between the first electrode 131 and the second electrode 136 have different thicknesses at respective positions, and have a fine cavity change according to a change in thickness. Accordingly, spectra for the respective thicknesses are combined by a constructive phenomenon, leading to an effect of improving the luminance viewing angle.

For example, the hole injection layer 132 includes a first flat portion FA1, a first curved portion CA1, and a second curved portion CA2. The plurality of curved surfaces of the cross-sectional profile of the hole injection layer 132 are provided by the first curved portion CA1 and the second curved portion CA2.

The first flat portion FA1 is disposed between the first curved portion CA1 and the second curved portion CA2. In the first flat portion FA1, a height of a central portion of the first flat portion FA1 may not be identical to a height of outer portions of the first flat portion FA1 adjacent to the first curved portion CA1 and the second curved portion CA2. For example, the first flat portion FA1 may have a thickness variation of 2 nm or less or 1 nm or less.

For example, a ratio of a width X1 of the first flat portion FA1 to a sum of a width Y1 of the first curved portion CA1 and a width Y2 of the second curved portion CA2 may be 3:7 to 7:3 or 4:6 to 6:4. In this case, a luminance viewing angle can be greatly improved while maintaining high efficiency of the display apparatus.

Each of the first curved portion CA1 and the second curved portion CA2 is a section in which a thickness decreases toward an inner portion of the hole injection layer 132 adjacent to the first flat portion FA1 from an outer portion of the hole injection layer 132 adjacent to the bank BNK. In other words, the first curved portion CA1 and the second curved portion CA2 each have a proximal end adjacent to the first flat portion FA1 and a distal end away from the first flat portion FA1, and for each of the first curved portion CA1 and the second curved portion CA2, the thickness decreases toward the proximal end from the distal end. For example, a difference ΔZ between a smallest thickness and a greatest thickness of each of the first curved portion CA1 and the second curved portion CA2 may be 15 nm to 150 nm, 20 nm to 150 nm, 30 nm to 100 nm, or 50 nm to 100 nm. When the difference ΔZ between the smallest thickness and the greatest thickness is less than 15 nm, an effect of increasing a luminance viewing angle may be insignificant. Conversely, when the difference between the smallest thickness and the greatest thickness exceeds 150 nm, emission efficiency may decrease. In FIG. 2, it is illustrated that the difference between the smallest thickness and the greatest thickness of the first curved portion CA1 and the difference between the smallest thickness and the greatest thickness of the second curved portion CA2 are identical to each other, but embodiments of the present disclosure are not limited thereto.

The hole injection layer 132 may be formed by a solution process. When the hole injection layer 132 is formed by a deposition process, the hole injection layer 132 is formed in a flat shape along a lower shape thereof. Accordingly, the hole injection layer 132 may be formed by a solution process so that the hole injection layer 132 has a cross-sectional profile having a U-shape. For example, the hole injection layer 132 may be formed by a solution process such as inkjet or nozzle printing, but embodiments of the present disclosure are not limited thereto.

For example, the hole injection layer 132 may be formed of a polymer having a weight average molecular weight of 11,000 g/mol or more, 11,000 g/mol to 200,000 g/mol, or 15,000 g/mol to 170,000 g/mol. In this case, the hole injection layer 132 having a cross-sectional profile of a U-shape may be formed. Further, since the difference between the smallest thickness and the greatest thickness of the hole injection layer 132 is 15 nm or more, which is large, there is an effect of improving a luminance viewing angle.

For example, the hole injection layer 132 may include an organic material including fluorine. For example, the hole injection layer 132 may include an organic material in which some atoms or functional groups of the polymer are substituted with fluorine or a functional group including fluorine. For example, the hole injection layer 132 may include a material in which some atoms or functional groups of the polymer such as polyimide, styrene, and methyl methacrylate are substituted with fluorine or a functional group including fluorine. As another example, the hole injection layer 132 may be a fluorine-based polymer such as polytetrafluoroethylene.

A hole transport layer may be further included as a lower organic layer. The hole transport layer may be disposed on the hole injection layer 132. For example, the hole transport layer may be formed on the hole injection layer 132 by a deposition process. In this case, the hole transport layer is conformally deposited along the surface of the hole injection layer 132. Accordingly, the hole transport layer may be formed with a constant thickness according to the cross-sectional profile of the hole injection layer 132. However, a method of forming the hole transport layer is not limited to the deposition process, and the hole transport layer may be formed by other methods such as a solution process and the like.

The light emitting layer 133 is disposed on the hole injection layer 132. The light emitting layer 133 emits light by including a light emitting material therein. The light emitting layer 133 may be formed to emit light of a color corresponding to the sub-pixel. Further, the light emitting layer 133 may be formed of a single layer or multiple layers. Unlike the first electrode 131, the light emitting layer 133 may be formed as a single layer without being separated in the plurality of sub-pixels. The light emitting layer 133 is disposed to cover the hole injection layer 132 and the bank BNK. A structure of the light emitting layer 133 is not limited thereto. As another embodiment of the present disclosure, the light emitting layer 133 may be formed separately for each of the plurality of sub-pixels, similar to the first electrode 131. For example, the light emitting layer 133 may be disposed to overlap the first electrode 131 and exposed without being covered by the bank BNK.

As described above, the light emitting layer 133 may be formed by a deposition process. When a light emitting material is deposited on the hole injection layer 132 having the cross-sectional profile of a U-shape, the light emitting material is conformally deposited along the surface of the hole injection layer 132. For example, the light emitting layer 133 is formed to have a constant thickness to correspond to the cross-sectional profile of the hole injection layer 132. For example, the light emitting layer 133 may have a thickness variation of 2 nm or less or 1 nm or less for process reasons.

For example, the thickness of the light emitting layer 133 is constant, but the total thickness of the layers stacked between the first electrode 131 and the second electrode 136 is not constant due to the cross-sectional profile of the hole injection layer 132. Due to changes in thickness of the layers stacked between the first electrode 131 and the second electrode 136, a multi-cavity effect may be obtained, so that a luminance viewing angle of the display apparatus may increase.

An upper organic layer is disposed on the light emitting layer 133. For example, the upper organic layer may include the electron transport layer 134.

The electron transport layer 134 is disposed on the light emitting layer 133. The electron transport layer 134 may be conformally formed along a surface of the light emitting layer 133 by a deposition process. Accordingly, the electron transport layer 134 may be formed to correspond to the cross-sectional profile of the hole injection layer 132.

The electron transport layer 134 is a layer that accelerates and transports electrons to the light emitting layer 133. The electron transport layer 134 allows electrons supplied from the second electrode 136 to be easily transferred to the light emitting layer 133.

For example, the electron transport layer 134 may include imidazole, oxadiazole, triazole, phenanthroline, benzoxazole, benzothiazole, benzimidazole, triazine, and derivatives thereof, but embodiments of the present disclosure are not limited thereto. For example, the electron transport layer 134 may include one of Liq (8-hydroxyquinolinolato-lithium), PBD (2-(4-biphenyl)-5-(4-tert-butylphenyl)-1,3,4-oxadiazole), TAZ (3-(4-biphenyl)4-phenyl-5-tert-butylphenyl-1,2,4-triazole), spiro-PBD, BCP(2,9-Dimethyl-4,7-diphenyl-1,10-phenanthroline), and BAlq (bis(2-methyl-8-quinolinolate)-4-(phenylphenolato)aluminum), but embodiments of the present disclosure are not limited thereto.

The electron injection layer 135 is disposed on the electron transport layer 134. The electron injection layer 135 may be conformally formed along a surface of the electron transport layer 134 by a deposition process. Accordingly, the electron injection layer 135 may be formed to correspond to the cross-sectional profile of the hole injection layer 132.

The electron injection layer 135 allows electrons supplied from the second electrode 136 to be smoothly injected into the electron transport layer 134. The electron injection layer 135 may be formed of an inorganic material and/or an organic material. For example, the electron injection layer 135 may be formed to include one or more of BaF₂, LiF, CsF, NaF, BaF₂, Li₂O, BaO, lithium quinolate (Liq), and lithium benzoate, but embodiments of the present disclosure are not limited thereto.

The second electrode 136 is disposed on the electron injection layer 135. The second electrode 136 may be conformally formed along a surface of the electron injection layer 135 by a deposition process. Accordingly, the second electrode 136 may be formed to correspond to the cross-sectional profile of the hole injection layer 132.

The second electrode 136 may be formed of a metal material having a low work function in order to smoothly supply electrons to the light emitting layer 133. For example, the second electrode 136 may be formed of one or more metal materials among Ca, Ba, Al, Ag, and an alloy including one or more of them, but embodiments of the present disclosure are not limited thereto.

The second electrode 136 is not patterned for each sub-pixel, but is formed as a single layer. When the display apparatus 100 is driven in the top emission method, the second electrode 136 may be formed to be very thin and substantially transparent.

The protective layer 140 is disposed on the second electrode 136 to protect the light emitting device 130. The protective layer 140 suppresses or prevents external moisture or oxygen from penetrating into the light emitting device 130 and deteriorating the light emitting device 130. For example, the protective layer 140 may be formed of a single layer or multiple layers. For example, the protective layer 140 may have a stacked structure in which an inorganic layer formed of an inorganic insulating material and an organic layer formed of an organic material are stacked, but embodiments of the present disclosure are not limited thereto.

As another embodiment of the present disclosure, the capping layer CPL may be further included between the second electrode 136 and the protective layer 140. Similar to the second electrode 136, the capping layer CPL is not patterned for each sub-pixel but is disposed as a single layer on the second electrode 136. The capping layer CPL may improve light efficiency and a viewing angle by improving optical characteristics of the organic light emitting device 130. Further, the capping layer CPL protects the second electrode 136 from deterioration.

The capping layer CPL and the protective layer 140 may also be formed to have a constant thickness to correspond to the cross-sectional profile of the hole injection layer 132.

In the display apparatus 100 according to an example embodiment of the present disclosure, the hole injection layer 132 has a cross-sectional profile of a U-shape and includes the light emitting layer 133 formed on the hole injection layer 132 by a deposition process. Accordingly, the light emitting layer 133 is formed to have a constant thickness along the cross-sectional profile of the hole injection layer 132, but the total thickness of the layers stacked between the first electrode 131 and the second electrode 136 is not constant. As described above, as the thickness of the light emitting layer 133 is constant, but the thickness of the layers between the first electrode 131 and the second electrode 136 is not constant, a multi-cavity effect may be obtained, so there is an effect of improving a luminance viewing angle of the display apparatus while maintaining high efficiency of the display apparatus.

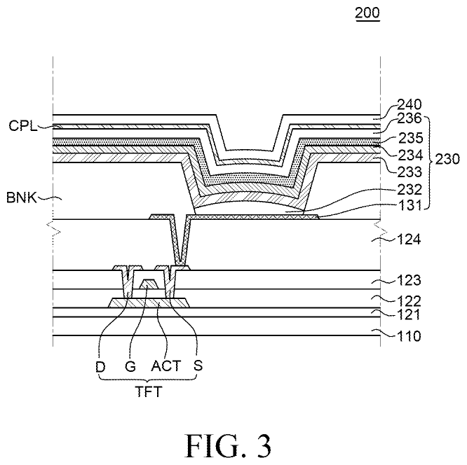

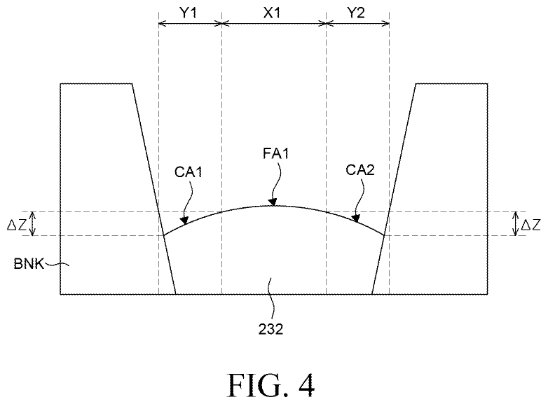

FIGS. 3 and 4 are views for explaining a display apparatus according to another example embodiment of the present disclosure. FIG. 3 is a cross-sectional view of a display apparatus according to another example embodiment of the present disclosure. FIG. 4 is a view for explaining a cross-sectional profile of a hole transport layer according to another example embodiment of the present disclosure. A display apparatus 200 shown in FIGS. 3 and 4 is substantially identical to the display apparatus 100 shown in FIGS. 1 and 2 except for differences in shapes of a hole injection layer and a light emitting layer, an electron transport layer, and an electron injection layer stacked on an upper portion of the hole injection layer. In FIG. 4, only the bank and the hole transport layer are shown for convenience of explanation, and an illustration of other components may be omitted.

Referring to FIGS. 3 and 4, a hole injection layer 232 may have a cross-sectional profile of a ∩-shape. For example, the hole injection layer 232 includes a first flat portion FA1, a first curved portion CA1, and a second curved portion CA2. The plurality of curved surfaces of the cross-sectional profile of the hole injection layer 232 are provided by the first curved portion CA1 and the second curved portion CA2.

The first flat portion FA1 is disposed between the first curved portion CA1 and the second curved portion CA2. In the first flat portion FA1, a height of a central portion of the first flat portion FA1 may not be identical to a height of outer portions of the first flat portion FA1 adjacent to the first curved portion CA1 and the second curved portion CA2. For example, the first flat portion FA1 may have a thickness variation of 2 nm or less or 1 nm or less.

For example, a ratio of a width X1 of the first flat portion FA1 to a sum of a width Y1 of the first curved portion CA1 and a width Y2 of the second curved portion CA2 may be 3:7 to 7:3 or 4:6 to 6:4. In this case, a luminance viewing angle may be greatly improved while maintaining high efficiency of the display apparatus.

Each of the first curved portion CA1 and the second curved portion CA2 is a section in which a thickness increases toward an inner portion of the hole injection layer 132 adjacent to the first flat portion FA1 from an outer portion of the hole injection layer 132 adjacent to the bank BNK. In other words, the first curved portion CA1 and the second curved portion CA2 each have a proximal end adjacent to the first flat portion FA1 and a distal end away from the first flat portion FA1, and for each of the first curved portion CA1 and the second curved portion CA2, the thickness increases toward the proximal end from the distal end. For example, a difference ΔZ between a smallest thickness and a greatest thickness of each of the first curved portion CA1 and the second curved portion CA2 may be 15 nm to 80 nm, 20 nm to 80 nm, 30 nm to 80 nm, or 20 nm to 60 nm. When the difference ΔZ between the smallest thickness and the greatest thickness is less than 15 nm, an effect of increasing a luminance viewing angle may be insignificant. Conversely, when the difference between the smallest thickness and the greatest thickness exceeds 80 nm, luminous efficiency (or emission efficiency) may decrease. When the cross-sectional profile has ∩-shape, a pile-up phenomenon is weaker at a portion adjacent to the bank, compared to the case of the U-shape, so there is a smaller thickness difference compared to the case of the U-shape. In FIG. 4, it is illustrated that the difference between the smallest thickness and the greatest thickness of the first curved portion CA1 and the difference between the smallest thickness and the greatest thickness of the second curved portion CA2 are substantially identical to each other, but embodiments of the present disclosure are not limited thereto.

The hole injection layer 232 may be formed by a solution process. When the hole injection layer 232 is formed by a deposition process, it is formed in a flat shape along a lower shape thereof. Accordingly, the hole injection layer 232 may be formed by a solution process to have a cross-sectional profile having a ∩-shape.

For example, the hole injection layer 232 may be formed of an oligomer having a weight average molecular weight of 2,000 g/mol or less, or 1,200 g/mol to 1,600 g/mol. For example, the hole injection layer 232 having the cross-sectional profile of a 11-shape may be formed. Further, since the difference between the smallest thickness and the greatest thickness of the hole injection layer 232 is 15 nm or more, and thus, there is an effect of improving a luminance viewing angle.

For example, the hole injection layer 232 may include an organic material in which some atoms or functional groups of a polymer are substituted with fluorine or a functional group including fluorine. For example, the hole injection layer 232 may include a material in which some atoms or functional groups of a polymer such as polyimide, styrene, and methyl methacrylate are substituted with fluorine or a functional group including fluorine, or a fluorine-based polymer such as polytetrafluoroethylene.

As another embodiment of the present disclosure, a hole transport layer may be further included as a lower organic layer. For example, the hole transport layer may be disposed on the hole injection layer 232 by a deposition process, but embodiments of the present disclosure are not limited thereto.

A light emitting layer 233 is stacked on the hole injection layer 232. The light emitting layer 233 is formed on the hole injection layer 232 having the cross-sectional profile of a n-shape by a deposition process. The light emitting layer 233 is conformally deposited along a surface of the hole injection layer 232 to have a constant thickness.

Accordingly, the thickness of the light emitting layer 233 is constant, but a total thickness of layers stacked between the first electrode 131 and the second electrode 236 is not constant due to the cross-sectional profile of the hole injection layer 232. Due to a change in the thickness of the layers stacked between the first electrode 131 and the second electrode 236, a multi-cavity effect may be obtained, so that a luminance viewing angle of the display apparatus can increase.

An electron transport layer 234, an electron injection layer 235, and a second electrode 236 are sequentially stacked on the light emitting layer 233 to form a light emitting device 230. Each of the electron transport layer 234, the electron injection layer 235, and the second electrode 236 may be conformally formed along a surface of a lower layer thereof. Each of the electron transport layer 234, the electron injection layer 235, and the second electrode 236 may be formed to correspond to the cross-sectional profile of the hole injection layer 232 having a ∩-shape between the bank BNK.

A capping layer CPL and a protective layer 240 are sequentially stacked on the light emitting device 230. The capping layer CPL and the protective layer 240 are identical to the capping layer CPL and the protective layer 140 of the display apparatus 100 shown in FIGS. 1 and 2 except that the capping layer CPL and the protective layer 240 have a shape corresponding to the cross-sectional profile of the hole injection layer 232 having a ∩-shape. Thus, redundant descriptions may be omitted.

In the display apparatus 200 according to an example embodiment of the present disclosure, the hole injection layer 232 has a cross-sectional profile of a ∩-shape, and the display apparatus 200 includes the light emitting layer 233 formed on the hole injection layer 232 by a deposition process. Accordingly, the light emitting layer 233 is formed with a constant thickness along the cross-sectional profile of the hole injection layer 232 having ∩-shape, but the total thickness of the layers stacked between the first electrode 131 and the second electrode 236 is not constant. In this way, as the thickness of the light emitting layer 233 is constant, but the thickness of the layers between the first electrode 131 and the second electrode 236 is not constant, a multi-cavity effect may be obtained, so there is an effect of improving a luminance viewing angle of the display apparatus while maintaining high efficiency of the display apparatus.

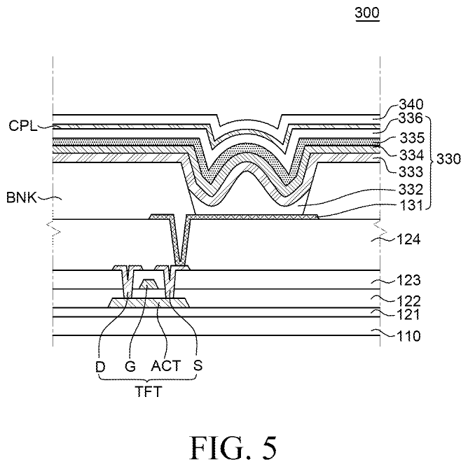

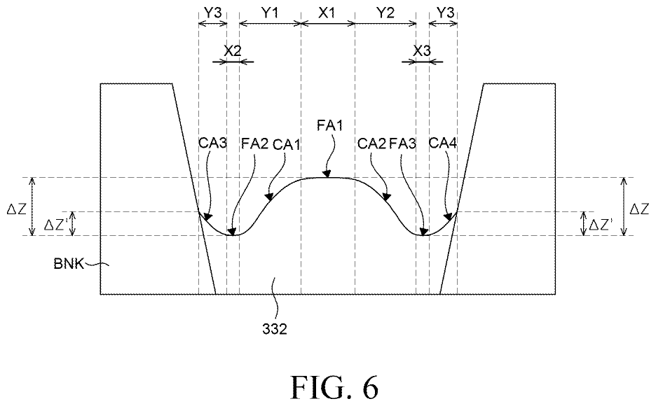

FIGS. 5 and 6 are views for explaining a display apparatus according to another example embodiment of the present disclosure. FIG. 5 is a cross-sectional view of a display apparatus according to still another example embodiment of the present disclosure. FIG. 6 is a view for explaining a cross-sectional profile of a hole transport layer according to still another example embodiment of the present disclosure. A display apparatus 300 illustrated in FIGS. 5 and 6 is substantially identical to the display apparatus 100 illustrated in FIGS. 1 and 2 except for differences in shapes of a hole injection layer and a light emitting layer, an electron transport layer, and an electron injection layer stacked on an upper portion of the hole injection layer. In FIG. 6, only the bank and the hole transport layer are shown for convenience of explanation, and an illustration of other components may be omitted.

Referring to FIGS. 5 and 6, a hole injection layer 332 may have a a cross-sectional profile of a W-shape. For example, the hole injection layer 232 includes a first flat portion FA1, a first curved portion CA1, a second curved portion CA2, a second flat portion FA2, and a third curved portion CA3, a third flat portion FA3, and a fourth curved portion CA4. The plurality of curved surfaces of the cross-sectional profile of the hole injection layer 332 are provided by the first curved portion CA1, the second curved portion CA2, the third curved portion CA3, and a fourth curved portion CA4.

The first flat portion FA1 is disposed at a central portion between the bank BNK. The first flat portion FA1 is disposed between the first curved portion CA1 and the second curved portion CA2. In the first flat portion FA1, a height of a central portion of the first flat portion FA1 may not be identical to a height of outer portions adjacent to the first curved portion CA1 and the second curved portion CA2. For example, the first flat portion FA1 may have a thickness variation of 2 nm or less or 1 nm or less.

The first curved portion CA1 is adjacent to one portion of the first flat portion FA1, and the second curved portion CA2 is adjacent to the other portion of the first flat portion FA1. The first curved portion CA1 and the second curved portion CA2 may be disposed in a symmetrical structure with the first flat portion FA1 interposed therebetween. Each of the first curved portion CA1 and the second curved portion CA2 is a portion in which a thickness increases toward an inner portion of the hole injection layer 332 adjacent to the first flat portion FA1 from an outer portion of the hole injection layer 132 adjacent to the bank BNK. In other words, the first curved portion CA1 and the second curved portion CA2 each have a proximal end adjacent to the first flat portion FA1 and a distal end away from the first flat portion FA1, and for each of the first curved portion CA1 and the second curved portion CA2, the thickness increases toward the proximal end from the distal end. For example, a difference ΔZ between a smallest thickness and a greatest thickness of each of the first curved portion CA1 and the second curved portion CA2 may be 15 nm to 80 nm, 20 nm to 80 nm, 30 nm to 80 nm, or 20 nm to 60 nm. When the difference ΔZ between the smallest thickness and the greatest thickness is less than 15 nm, an effect of increasing a luminance viewing angle may be insignificant. Conversely, when the difference between the smallest thickness and the greatest thickness exceeds 80 nm, luminous efficiency may decrease. In FIG. 6, it is illustrated that the difference between the smallest thickness and the greatest thickness of the first curved portion CA1 and the difference between the smallest thickness and the greatest thickness of the second curved portion CA2 are substantially identical to each other, but embodiments of the present disclosure are not limited thereto.

The first curved portion CA1 is disposed between the second flat portion FA2 and the first flat portion FA1. The second flat portion FA2 is located between the first curved portion CA1 and the third curved portion CA3. Accordingly, one portion of the second flat portion FA2 is adjacent to the first curved portion CA1, and the other portion of the second flat portion FA2 is adjacent to the third curved portion CA3. A height of a central portion of the second flat portion FA2 may not be identical to a height of an outer portion of the second flat portion FA2 since the second flat portion FA2 has a thickness variation. For example, the thickness variation of the second flat portion FA2 may be 2 nm or less or 1 nm or less.

The second curved portion CA2 is disposed between the third flat portion FA3 and the first flat portion FA1. The third flat portion FA3 is located between the second curved portion CA2 and the fourth curved portion CA4. Accordingly, one portion of the third flat portion FA3 is adjacent to the second curved portion CA2, and the other portion of the third flat portion FA3 is adjacent to the fourth curved portion CA4. The third flat portion FA3 and the second flat portion FA2 may be disposed in a symmetrical structure with the first curved portion CA1, the first flat portion FA1, and the second curved portion CA2 interposed therebetween. A height of a central portion of the third flat portion FA3 may not be identical to a height of an outer portion of the third flat portion FA3 since the third flat portion FA3 has a thickness variation. For example, the third flat portion FA3 may have a thickness variation of 2 nm or less or 1 nm or less.

One portion of the third curved portion CA3 is disposed adjacent to the second flat portion FA2 and the other portion of the third curved portion CA3 is disposed adjacent to the bank BNK. The third curved portion CA3 is a portion in which a thickness decreases toward an inner portion of the hole injection layer 332 adjacent to the second flat portion FA2 from an outer portion of the hole injection layer 332 adjacent to the bank BNK. In other words, the third curved portion CA3 has a proximal end adjacent to the second flat portion FA2 and a distal end away from the second flat portion FA2, and for the third curved portion CA3, the thickness decreases toward the proximal end from the distal end of the third curved portion CA3. For example, a difference ΔZ′ between a smallest thickness and a greatest thickness of the third curved portion CA3 may be 10 nm to 50 m or 15 nm to 40 nm. When the difference ΔZ′ between the smallest thickness and the greatest thickness of the third curved portion CA3 is less than 10 nm, an effect of increasing a luminance viewing angle may be insignificant. Conversely, when the difference between the smallest thickness and the greatest thickness exceeds 50 nm, luminous efficiency may decrease.

One portion of the fourth curved portion CA4 is disposed adjacent to the third flat portion FA3 and the other portion of the fourth curved portion CA4 is disposed adjacent to the bank BNK. The fourth curved portion CA4 is a portion in which a thickness decreases toward the inner portion of the hole injection layer 332 adjacent to the third flat portion FA3 from the outer portion of the hole injection layer 332 adjacent to the bank BNK. In other words, the fourth curved portion CA4 has a proximal end adjacent to the third flat portion FA3 and a distal end away from the third flat portion FA3, and for the fourth curved portion CA4, the thickness decreases toward the proximal end from the distal end of the fourth curved portion CA4. For example, a difference ΔZ′ between a smallest thickness and a greatest thickness of the fourth curved portion CA4 may be 10 nm to 50 m or 15 nm to 40 nm. When the difference ΔZ′ between the smallest thickness and the greatest thickness of the fourth curved portion CA4 is less than 10 nm, an effect of increasing a luminance viewing angle may be insignificant. Conversely, when the difference between the smallest thickness and the greatest thickness exceeds 50 nm, luminous efficiency may decrease. The fourth curved portion CA4 and the third curved portion CA3 may be disposed in a symmetrical structure with the second flat portion FA2, the second curved portion CA2, the first flat portion FA1, the third curved portion CA3, and the third flat portion FA3 interposed therebetween.

In FIG. 6, it is illustrated that the difference between the smallest thickness and the greatest thickness of the third curved portion CA3 and the difference between the smallest thickness and the greatest thickness of the fourth curved portion CA4 are substantially identical to each other, but embodiments of the present disclosure are not limited thereto.

To maximize the efficiency and luminance viewing angle of the display apparatus 300, a width X1 of the first flat portion FA1, a width Y1 of the first curved portion CA1, a width Y2 of the second curved portion CA2, a width X2 of the second flat portion FA2, a width X3 of the third flat portion FA3, a width Y3 of the third curved portion CA3, and a width Y4 of the fourth curved portion CA4 may be adjusted. For example, (Y3+Y4):(X2+X3):(Y1+Y2): X1 may be (0.5 to 1.0):(1.0 to 2.0):(4.5 to 7.0):(1.5 to 3.0). As another embodiment of the present disclosure, (Y3+Y4): (X2+X3):(Y1+Y2): X1 may be (0.5 to 1.0):(1.0 to 1.5):(4.8 to 5.8):(2.0 to 3.0). As another embodiment of the present disclosure, (Y3+Y4):(X2+X3):(Y1+Y2): X1 may be (0.5 to 1.0):(1.0 to 1.5):(6.0 to 7.0):(1.5 to 2.0). The luminance viewing angle may be greatly improved while maintaining high luminous efficiency of the display apparatus 300 within the ranges described above.

The hole injection layer 332 may be formed by a solution process. In this case, the hole injection layer 332 may be easily formed to have a cross-sectional profile of a W-shape. When the hole injection layer 332 is formed by a solution process, it is formed in a flat shape along a lower shape thereof. In other words, the cross-sectional profile of the hole injection layer 332 has a flat shape on a side facing towards the first electrode 131.

For example, the hole injection layer 332 may be formed of an oligomer having a weight average molecular weight of 2,000 g/mol or less or 1,200 g/mol to 1,600 g/mol. In this case, the hole injection layer 332 having the W-shaped cross-sectional profile may be easily formed.

For example, the hole injection layer 332 may include an organic material in which some atoms or functional groups of a polymer are substituted with fluorine or a functional group including fluorine. For example, the hole injection layer 332 may include a material in which some atoms or functional groups of a polymer such as polyimide, styrene, and methyl methacrylate are substituted with fluorine or a functional group including fluorine, or a fluorine-based polymer such as polytetrafluoroethylene.

As another embodiment of the present disclosure, a hole transport layer formed on the hole injection layer 332 by a deposition process may be further included.

A light emitting layer 333 is stacked on the hole injection layer 332. The light emitting layer 333 is formed on the hole injection layer 332 having the cross-sectional profile of a W-shape by a deposition process. The light emitting layer 333 is conformally deposited along a surface of the hole injection layer 332 to have a constant thickness.

An electron transport layer 334, an electron injection layer 335, and a second electrode 336 are sequentially stacked on the light emitting layer 333 to form a light emitting device 330. Each of the electron transport layer 334, the electron injection layer 335, and the second electrode 336 may be conformally formed along a surface of a lower layer thereof. Each of the electron transport layer 334, the electron injection layer 335, and the second electrode 336 may be formed to correspond to the cross-sectional profile of the hole injection layer 332 having a W-shape between the bank BNK.

A capping layer CPL and a protective layer 340 are sequentially stacked on the light emitting device 330. The capping layer CPL and the protective layer 340 are identical to the capping layer CPL and the protective layer 140 of the display apparatus 100 shown in FIGS. 1 and 2 except that the capping layer CPL and the protective layer 340 have a shape corresponding to the cross-sectional profile of the hole injection layer 332 having a W-shape. Thus, redundant descriptions may be omitted.

In the display apparatus 300 according to an example embodiment of the present disclosure, the hole injection layer 332 has a cross-sectional profile of a W-shape, and the display apparatus 300 includes the light emitting layer 333 formed on the hole injection layer 332 by a deposition process. Accordingly, the light emitting layer 333 is formed with a constant thickness along the cross-sectional profile of the hole injection layer 332 having a W-shape, but a total thickness of layers stacked between the first electrode 131 and the second electrode 336 is not constant. Due to a change in the thickness of the layers stacked between the first electrode 131 and the second electrode 336, a multi-cavity effect may be obtained, so there is an effect of greatly improving a luminance viewing angle of the display apparatus while maintaining high efficiency of the display apparatus.

Hereinafter, effects of the present disclosure will be described in more detail through Embodiments of the present disclosure and Comparative Examples. However, the following Embodiments of the present disclosure are for illustration of the present disclosure, and embodiments of the present disclosure are not limited by the following Embodiments.

### Experimental Example 1

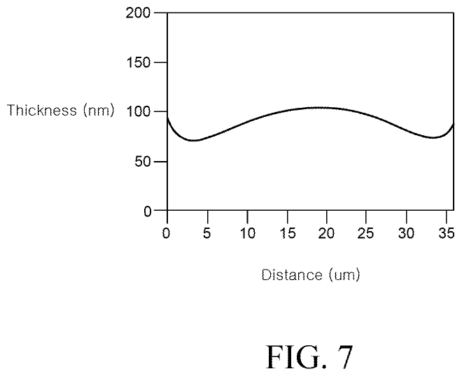

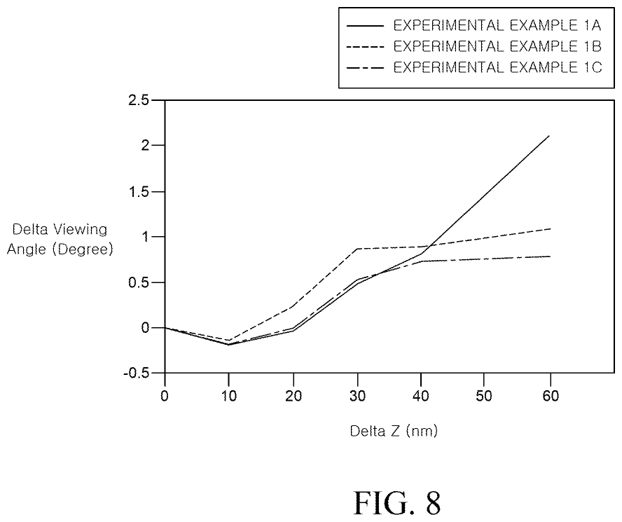

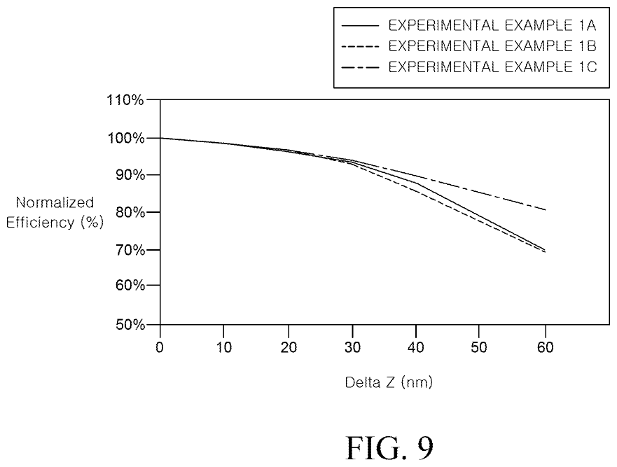

Through simulations of specimens in which a hole injection layer having ∩-shape as shown in FIG. 4 is formed in a bank on the substrate, a thickness profile, efficiency and a viewing angle were analyzed. At this time, a specimen in which a ratio of a width X1 of a first flat portion to a sum of a width Y1 of a first curved portion CA1 and a width Y2 of a second curved portion CA2, that is, X1:(Y1+Y2) is 3:7 (hereinafter, Experimental Example 1A); a specimen in which X1:(Y1+Y2) is 5:5 (hereinafter, Experimental Example 1B); and a specimen in which X1:(Y1+Y2) is 7:3 (hereinafter, Experimental Example 1C) were respectively simulated. Consequent results are illustrated in FIGS. 7, 8 and 9. FIG. 7 is a graph showing a thickness profile of a hole injection layer having a ∩-shape. FIG. 8 is a graph showing a change in viewing angle according to a difference (Δ) between a smallest thickness and a greatest thickness of the hole injection layer having a ∩-shape. FIG. 9 is a graph showing a change in efficiency according to the difference (Δ) between the smallest thickness and the greatest thickness of the hole injection layer having ∩-shape. For reference, ΔZ of 0 in FIGS. 8 and 9 means that the hole injection layer is formed flat.

Referring to FIG. 7, it can be seen that the hole injection layer having ∩-shape exhibits a pile-up phenomenon on an outer portion of the hole injection layer adjacent to the bank. Referring to FIG. 8, it can be seen that the viewing angle increases as the difference ΔZ between the smallest thickness and the greatest thickness of the hole injection layer having ∩-shape increases. It can be seen that the effect of increasing the viewing angle significantly increases when ΔZ is 15 nm or more and 20 nm or more. Further, it can be seen that the effect of increasing the viewing angle is maximized when widths of the curved portions CA1 and CA2 are relatively wide, where X1:(Y1+Y2) is 3:7, rather than 7:3. Referring to FIG. 9, even if ΔZ increases, luminous efficiency (or emission efficiency) is maintained relatively high, and it can be seen that the efficiency is more excellent when ΔZ is 40 nm or less.

### Experimental Example 2

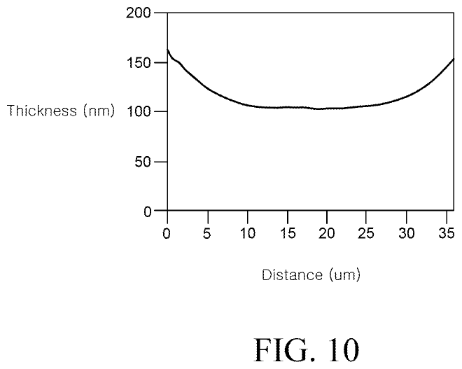

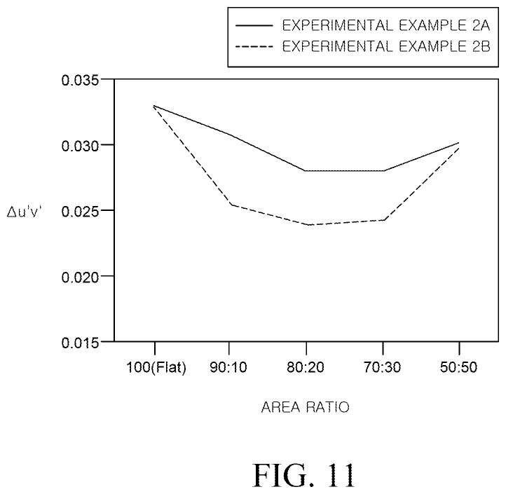

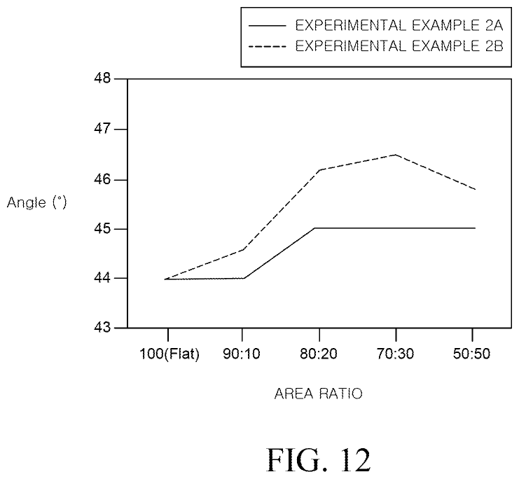

Through simulations of specimens in which a hole injection layer having a U-shape as illustrated in FIG. 2 is formed in a bank on the substrate, a thickness profile, a color viewing angle, and a luminance viewing angle were analyzed. At this time, Experimental Example 2A in which a difference ΔZ between a greatest thickness and a smallest thickness of each of a first curved portion CA1 and a second curved portion CA2 is 46 nm, and Experimental Example 2B in which the difference ΔZ between the greatest thickness and the smallest thickness is 68 nm were respectively simulated. Consequent results are shown in FIGS. 10, 11 and 12. FIG. 10 is a graph showing a thickness profile of a hole transport layer according to Experimental Example 2B. FIG. 11 is a graph showing changes in luminance viewing angle of a hole injection layer having a U-shape. FIG. 12 is a graph showing changes in color viewing angle of the hole injection layer having a U-shape. For reference, in FIGS. 11 and 12, an area ratio is a ratio of a width X1 of a first flat portion to a sum of a width Y1 of a first curved portion CA1 and a width Y2 of a second curved portion CA2. The area ratio of 100 means that the hole injection layer is formed flat without a curved portion.

Referring to FIG. 10, it can be confirmed that the hole injection layer has a U-shaped profile. Referring to FIG. 11, it can be seen that when the hole injection layer has a U-shape, the luminance viewing angle is greatly improved compared to a case where the hole injection layer is flat. Further, it can be confirmed that Experimental Example 2B, in which the difference ΔZ between the smallest thickness and the greatest thickness of the hole injection layer having a U-shape is relatively large, has a greater improvement effect in luminance viewing angle. Referring to FIG. 12, when the hole injection layer has a U-shape, it can be seen that the color viewing angle is greatly improved compared to the case where the hole injection layer is flat, and it can be seen that Experimental Example 2B having a relatively large ΔZ has a greater improvement effect in color viewing angle than Experimental Example 2A.

### Experimental Example 3

Through simulations of specimens in which a hole injection layer having a W-shape as shown in FIG. 6 is formed in a bank on the substrate, a thickness profile, a luminance viewing angle and efficiency were analyzed.

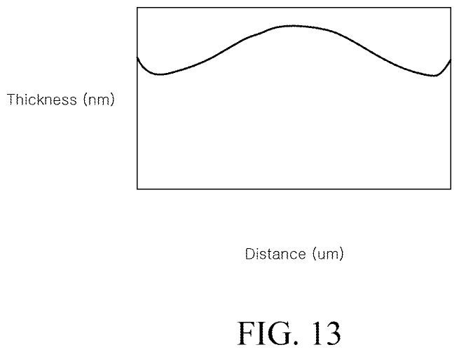

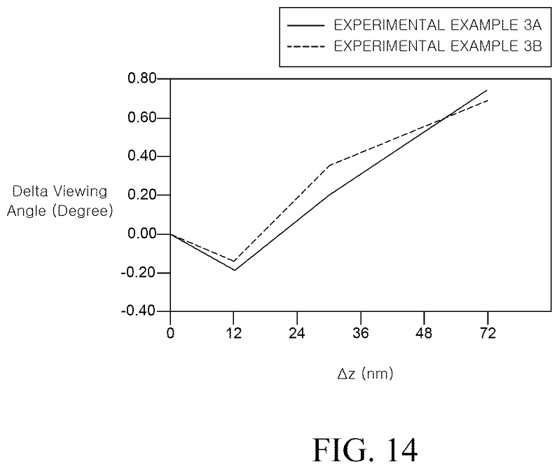

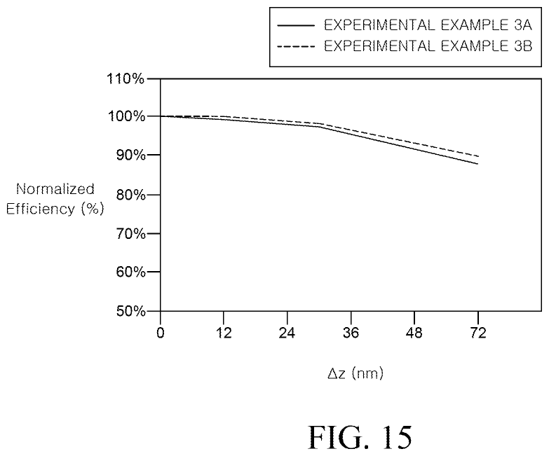

At this time, in FIG. 6, a specimen in which (Y3+Y4):(X2+X3):(Y1+Y2): X1 is 0.8: 1.2: 5.6: 2.4 (hereinafter, Experimental Example 3A); and a specimen in which (Y3+Y4):(X2+X3): (Y1+Y2): X1 is 0.8: 1.2: 6.4: 1.6 (hereinafter, Experimental Example 3B) were respectively simulated. Consequent results are shown in FIGS. 13, 14 and 15. FIG. 13 is a graph showing a thickness profile of a hole injection layer having a W-shape. FIG. 14 is a graph showing changes in viewing angle according to a difference (Δ) between a smallest thickness and a greatest thickness of the hole injection layer having a W-shape. FIG. 15 is a graph showing changes in efficiency according to the difference (Δ) between the smallest thickness and the greatest thickness of the hole injection layer having a W-shape. For reference, ΔZ of 0 in FIGS. 14 and 15 means that the hole injection layer is formed flat.

Referring to FIG. 13, it can be seen that the hole injection layer has a W-shaped profile. Referring to FIG. 14, it can be seen that the viewing angle increases as the difference ΔZ between the smallest thickness and the greatest thickness of the hole injection layer having a W-shape increases. It can be seen that an effect of increasing the viewing angle significantly increases when ΔZ is 15 nm or more. Further, it can be seen that a difference in the ratio of (Y3+Y4): (X2+X3):(Y1+Y2): X1 between Experimental Example 3A and Experimental Example 3B is not significant, so a difference in effect of increasing the viewing angle therebetween is also similar. Referring to FIG. 15, it can be seen that luminous efficiency is maintained relatively high even when ΔZ is increased.

A display apparatus according to one or more embodiments of the present disclosure are described below.

A display apparatus according to one or more embodiments of a present disclosure may comprise a substrate, a first electrode disposed on the substrate, a lower organic layer disposed on the first electrode, a light emitting layer disposed on the lower organic layer, and a second electrode disposed on the light emitting layer. The lower organic layer may have a cross-sectional profile including a plurality of curved surfaces. The lower organic layer may have a cross-sectional profile including a plurality of curved surfaces on a side facing towards the light emitting layer.

According to one or more embodiments of the present disclosure, the lower organic layer may include at least one of a hole injection layer or a hole transport layer.

According to one or more embodiments of the present disclosure, the lower organic layer may have a cross-sectional profile of one or more of U-shape, a ∩-shape, a W-shape, or a M-shape.

According to one or more embodiments of the present disclosure, the cross-sectional profile of the lower organic layer may have the U-shape. The lower organic layer may have a first curved portion, a second curved portion, and a first flat portion between the first curved portion and the second curved portion. The first curved portion and the second curved portion may have a shape in which a thickness decreases toward an inner portion from an outer portion of the lower organic layer. A thickness variation of the first flat portion may be 2 nm or less.

According to one or more embodiments of the present disclosure, the lower organic layer may have the cross-sectional profile of the U-shape. The lower organic layer may have a first curved portion, a second curved portion, and a first flat portion between the first curved portion and the second curved portion. The first curved portion and the second curved portion each may have a proximal end adjacent to the first flat portion and a distal end away from the first flat portion. The first curved portion and the second curved portion each may have a shape in which a thickness decreases toward the proximal end from the outer portion distal. A thickness variation of the first flat portion may be 2 nm or less.

According to one or more embodiments of the present disclosure, a difference between a smallest thickness and a greatest thickness of each of the first curved portion and the second curved portion may be in a range from 15 nm to 150 nm.

According to one or more embodiments of the present disclosure, a ratio of a width of the first flat portion to a sum of a width of the first curved portion and a width of the second curved portion may be in a range from 3:7 to 7:3.

According to one or more embodiments of the present disclosure, the cross-sectional profile of the lower organic layer may be the ∩-shape. The lower organic layer may be a first curved portion, a second curved portion, and a first flat portion between the first curved portion and the second curved portion. The first curved portion and the second curved portion may have a shape in which a thickness increases toward an inner portion from an outer portion of the lower organic layer. A thickness variation of the first flat portion may be 2 nm or less.

According to one or more embodiments of the present disclosure, the cross-sectional profile of the lower organic layer may be the ∩-shape. The lower organic layer may be a first curved portion, a second curved portion, and a first flat portion between the first curved portion and the second curved portion. The first curved portion and the second curved portion each may have a proximal end adjacent to the first flat portion and a distal end away from the first flat portion. The first curved portion and the second curved portion each may have a shape in which a thickness increases toward the proximal end from the distal end. A thickness variation of the first flat portion may be 2 nm or less.

According to one or more embodiments of the present disclosure, a difference between a smallest thickness and a greatest thickness of each of the first curved portion and the second curved portion may be in a range from 15 nm to 80 nm.

According to one or more embodiments of the present disclosure, a ratio of a width of the first flat portion to a sum of a width of the first curved portion and a width of the second curved portion may be in a range from 3:7 to 7:3.

According to one or more embodiments of the present disclosure, the cross-sectional profile of the lower organic layer may have the W-shape. The lower organic layer may include a first flat portion, a first curved portion disposed at a first portion of the first flat portion, a second curved portion disposed at a second portion of the first flat portion, a second flat portion at a first portion of the first curved portion, a third flat portion at a first portion of the second curved portion, a third curved portion disposed at a first portion of the second flat portion, and a fourth curved portion at a second portion of the third flat portion. The first curved portion and the second curved portion may be symmetrical to each other, the second flat portion and the third flat portion may be symmetrical to each other, and the third curved portion and the fourth curved portion may be symmetrical to each other. A thickness variation of each of the first flat portion, the second flat portion, and the third flat portion may be 2 nm or less.

According to one or more embodiments of the present disclosure, the first curved portion and the second curved portion may have a shape in which a thickness increases toward an inner portion from an outer portion of the lower organic layer, and wherein the third curved portion and the fourth curved portion may have a shape in which a thickness decreases toward the inner portion from the outer portion of the lower organic layer.

According to one or more embodiments of the present disclosure, the first curved portion and the second curved portion each may have a proximal end adjacent to the first flat portion and a distal end away from the first flat portion and the first curved portion and the second curved portion each may have a shape in which a thickness increases toward the proximal end from the distal end. The third curved portion may have a proximal end adjacent to the second flat portion and a distal end away from the second flat portion, and the third curved portion may have a shape in which a thickness decreases toward the proximal end from the distal end of the third curved portion. The fourth curved portion may have a proximal end adjacent to the third flat portion and a distal end away from the third flat portion, and the fourth curved portion may have a shape in which a thickness decreases toward the proximal end from the distal end of the fourth curved portion.

According to one or more embodiments of the present disclosure, a sum of a width of the third curved portion and a width of the fourth curved portion is a, a sum of a width of the second flat portion and a width of the third flat portion is b, and a sum of a width of the first curved portion and a width of the second curved portion is c, and a width of the first flat portion is d, a: b: c: d may be (0.5 to 1.0):(1.0 to 2.0):(4.5 to 7.0):(1.5 to 3.0).

According to one or more embodiments of the present disclosure, a difference between a smallest thickness and a greatest thickness of each of the first curved portion and the second curved portion may be in a range from 15 nm to 80 nm. A difference between a smallest thickness and a greatest thickness of each of the third curved portion and the fourth curved portion may be in a range from 10 nm to 50 nm.

According to one or more embodiments of the present disclosure, the lower organic layer may be formed by a solution process, and the light emitting layer may be formed by a deposition process. A thickness variation of the light emitting layer may be 2 nm or less.

According to one or more embodiments of the present disclosure, the cross-sectional profile of the lower organic layer may have the ∩-shape or the W-shape, and the lower organic layer may be formed of an oligomer having a weight average molecular weight of 2,000 g/mol or less.

According to one or more embodiments of the present disclosure, the cross-sectional profile of the lower organic layer may have the U-shape, and the lower organic layer may be formed of a polymer having a weight average molecular weight of 11,000 g/mol or more.

According to one or more embodiments of the present disclosure, the lower organic layer may include an organic material including fluorine.

According to one or more embodiments of the present disclosure, the organic material including fluorine may be a polymer with atoms or functional groups substituted with fluorine or a functional group including fluorine.

According to one or more embodiments of the present disclosure, a difference between a minimum thickness and a maximum thickness of the lower organic layer may be 15 nm or more.

According to one or more embodiments of the present disclosure, the cross-sectional profile of the lower organic layer may have a flat shape on a side facing towards the first electrode.

It will be apparent to those skilled in the art that various modifications and variations can be made in the present disclosure without departing from the scope of the present disclosure. Thus, it is intended that the present disclosure cover the modifications and variations of this disclosure and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate;
a first electrode disposed on the substrate;
a lower organic layer disposed on the first electrode;
a light emitting layer disposed on the lower organic layer; and
a second electrode disposed on the light emitting layer,
wherein the lower organic layer has a cross-sectional profile including a plurality of curved surfaces.

2. The display apparatus of claim 1, wherein the lower organic layer includes at least one of a hole injection layer or a hole transport layer.

3. The display apparatus of claim 1, wherein the lower organic layer has a cross-sectional profile of one or more of a U-shape, a ∩-shape, a W-shape, or a M-shape.

4. The display apparatus of claim 3, wherein the cross-sectional profile of the lower organic layer has the U-shape,
wherein the lower organic layer has a first curved portion, a second curved portion, and a first flat portion between the first curved portion and the second curved portion,
wherein the first curved portion and the second curved portion have a shape in which a thickness decreases toward an inner portion from an outer portion of the lower organic layer, and
wherein a thickness variation of the first flat portion is 2 nm or less.

5. The display apparatus of claim 4, wherein a difference between a smallest thickness and a greatest thickness of each of the first curved portion and the second curved portion is in a range from 15 nm to 150 nm.

6. The display apparatus of claim 4, wherein a ratio of a width of the first flat portion to a sum of a width of the first curved portion and a width of the second curved portion is in a range from 3:7 to 7:3.

7. The display apparatus of claim 3, wherein the cross-sectional profile of the lower organic layer has the ∩-shape,
wherein the lower organic layer has a first curved portion, a second curved portion, and a first flat portion between the first curved portion and the second curved portion,
wherein the first curved portion and the second curved portion have a shape in which a thickness increases toward an inner portion from an outer portion of the lower organic layer, and
wherein a thickness variation of the first flat portion is 2 nm or less.

8. The display apparatus of claim 7, wherein a difference between a smallest thickness and a greatest thickness of each of the first curved portion and the second curved portion is in a range from 15 nm to 80 nm.

9. The display apparatus of claim 7, wherein a ratio of a width of the first flat portion to a sum of a width of the first curved portion and a width of the second curved portion is in a range from 3:7 to 7:3.

10. The display apparatus of claim 3, wherein the cross-sectional profile of the lower organic layer has the W-shape,
wherein the lower organic layer includes a first flat portion, a first curved portion disposed at a first portion of the first flat portion, a second curved portion disposed at a second portion of the first flat portion, a second flat portion at a first portion of the first curved portion, a third flat portion at a second portion of the second curved portion, a third curved portion disposed at a first portion of the second flat portion, and a fourth curved portion disposed at a second portion of the third flat portion,
wherein the first curved portion and the second curved portion are symmetrical to each other, the second flat portion and the third flat portion are symmetrical to each other, and the third curved portion and the fourth curved portion are symmetrical to each other, and
wherein a thickness variation of each of the first flat portion, the second flat portion, and the third flat portion is 2 nm or less.

11. The display apparatus of claim 10, wherein the first curved portion and the second curved portion have a shape in which a thickness increases toward an inner portion from an outer portion of the lower organic layer, and
wherein the third curved portion and the fourth curved portion has a shape in which a thickness decreases toward the inner portion from the outer portion of the lower organic layer.

12. The display apparatus of claim 10, wherein when a sum of a width of the third curved portion and a width of the fourth curved portion is a, a sum of a width of the second flat portion and a width of the third flat portion is b, and a sum of a width of the first curved portion and a width of the second curved portion is c, and a width of the first flat portion is d,
a: b: c: d is (0.5 to 1.0):(1.0 to 2.0):(4.5 to 7.0):(1.5 to 3.0).

13. The display apparatus of claim 10, wherein a difference between a smallest thickness and a greatest thickness of each of the first curved portion and the second curved portion is in a range from 15 nm to 80 nm, and
wherein a difference between a smallest thickness and a greatest thickness of each of the third curved portion and the fourth curved portion is in a range from 10 nm to 50 nm.

14. The display apparatus of claim 1, wherein the lower organic layer is formed by a solution process, and the light emitting layer is formed by a deposition process.

15. The display apparatus of claim 3, wherein the cross-sectional profile of the lower organic layer has the ∩-shape or the W-shape, and the lower organic layer is formed of an oligomer having a weight average molecular weight of 2000 g/mol or less.

16. The display apparatus of claim 3, wherein the cross-sectional profile of the lower organic layer has the U-shape, and the lower organic layer is formed of a polymer having a weight average molecular weight of 11000 g/mol or more.

17. The display apparatus of claim 1, wherein the lower organic layer includes an organic material including fluorine.

18. The display apparatus of claim 17, wherein the organic material including fluorine includes a polymer with atoms or functional groups substituted with fluorine or a functional group including fluorine.

19. The display apparatus of claim 1, wherein a difference between a smallest thickness and a greatest thickness of the lower organic layer is 15 nm or more.

20. The display apparatus of claim 1, wherein the cross-sectional profile of the lower organic layer has a flat shape on a side facing towards the first electrode.
